(19) United States
(12) Patent Application Publication
(10) Pub. No.: US 2004/0201043 A1
(43) Pub. Date: Oct. 14, 2004

(54) Bit line contact hole and method for forming the same

(76) Inventors: Hui-Min Mao, Taipei (TW); Yi-Nan Chen, Taipei (TW)

Correspondence Address: QUINTERO LAW OFFICE, 1617 BROADWAY, 3RD FLOOR, SANTA MONICA, CA, 90404, US

(21) Appl. No.: 10/733,984

(22) Filed: Dec. 11, 2003

(30) Foreign Application Priority Data
Apr. 10, 2003 (TW) 92108223

(51) Int. Cl. H01L 21/82; H01L 29/94

(52) U.S. Cl. 257/208; 257/211; 257/296; 438/128; 438/129

(57) ABSTRACT

A method of forming a bit line contact hole. After transistors are formed on a substrate, a polysilicon layer conformally covers the transistors and the substrate. The polysilicon layer is defined to form an inner landing pad connecting with a doped region. A passivation layer is formed on the inner landing pad, the transistor and the substrate. An insulating layer with a flat surface is then formed on the passivation layer. A contact opening is formed in the insulating layer and the passivation layer to expose the inner landing pad. MO etching forms a recess of interconnecting landing pad pattern in the upper portion of the contact opening. MO deposition is then performed. The formed bit line contact structure comprises a bottom layer of a polysilicon inner landing pad, a contact plug and a top layer of an interconnected landing pad.

### BACKGROUND OF THE INVENTION

1. Field of the Invention

The present invention relates to a semiconductor manufacturing process and in particular to a method of forming a bit line contact hole.

2. Description of the Related Art

When manufacturing memory products such as trench-type DRAM, stacked-type DRAM and FLASH memory, in order to reduce the size of a chip, the conventional semiconductor process uses self-aligned contact (SAC) technology to define a reduced distance between two adjacent gate conductive structures.

Conventionally, in DRAM devices, the contact holes in the memory cell array area and the logic circuit area are formed in different processes. The contact hole is formed in the memory cell array area before the logic circuit area.

However, when forming the bit line contact hole by etching an insulating layer, silicon substrate consumption produces serious sub-sheathed voltage and affects the memory ability of the memory cell array area. As well, with increased integration, the gap narrows, such that etching the contact hole is more and more difficult, and contact hole opens occur, as shown in FIG. 3. Furthermore, shorts between the word line and the bit line can occur when the spacer of the transistor of the bit line is consumed, as shown in FIG. 4.

### SUMMARY OF THE INVENTION

Accordingly, an object of the invention is to provide a method of forming a bit line contact hole to avoid silicon consumption when etching the bit line contact hole.

It is another object of the invention to provide a method of forming a bit line contact hole that solves the difficulty of etching contact hole in a narrow gap between adjacent transistors and avoids opens in bit lines.

It is another object of the invention to provide a method of forming a bit line contact hole to prevent shorts between the word line and bit line.

The present invention provides a method of forming a bit line contact hole. After forming transistors on a substrate, a polysilicon layer conformally covers the transistors and the substrate. The polysilicon layer is defined to form an inner landing pad connecting with a doped region. A passivation layer is formed on the inner landing pad, the transistor and the substrate. An insulating layer with a flat surface is then formed on the passivation layer. A contact opening is formed in the insulating layer and the passivation layer to expose the inner landing pad. MO etching forms a recess of interconnecting landing pad pattern in the upper portion of the contact opening. MO deposition is then performed. The formed bit line contact structure comprises a bottom layer of a polysilicon inner landing pad, a contact plug, and a top layer of an interconnected landing pad.

The present invention provides another method of forming a bit line contact hole. First, a substrate having a transistor thereon and comprising a memory cell array area and a logic circuit area is provided. The transistor comprises a gate layer covered by a first insulating layer and a doped region. Next, a polysilicon layer is formed to conformally cover the substrate and the transistor. The polysilicon layer is subsequently defined to form an inner landing pad connecting with the doped region in the memory cell array area. A passivation layer is conformally formed on the inner landing pad, the transistor, and the substrate. A second insulating layer with a flat surface is then formed on the passivation layer. A first contact hole, a second contact hole, and a third contact hole are formed in the second insulating layer and the passivation layer, wherein the first contact hole exposes the surface of the inner landing pad in the memory cell array area, the second contact hole exposes the gate layer of the transistor in the logic circuit area, and the third contact hole exposes the doped region of the transistor in the logic circuit area. Finally, the first contact hole, the second contact hole, and the third contact hole are filled with a metal layer.

The present invention also provides a structure for a bit line contact hole. The structure comprises a substrate, a transistor, a inner landing pad, a passivation layer, a first insulating layer, a second insulating layer, a contact plug, and an interconnected landing pad. The transistor comprising a gate layer covered by a first insulating layer and a doped region is disposed on the substrate. The inner landing pad comprising a polysilicon layer is disposed on the doped region and parts of the transistor. The passivation layer is disposed on the inner landing pad, the transistor, and the substrate. The second insulating layer, having a flat surface, is disposed on the passivation layer. The contact plug electrically connecting with the inner landing pad is disposed on the second insulating layer and the passivation layer. The interconnected landing pad is disposed on the contact plug.

The thickness of the polysilicon layer can be about 100˜400 Å. The polysilicon layer can be defined by wet etching employing an HF solution comprising NH4F and HF at about 400˜500:1 ratio.

The material of the passivation layer may comprise silicon nitride. The thickness of the passivation layer can be about 110˜130 Å.

The second insulating layer can be a stacked layer comprising a boro-phospho silicate glass (BPSG) layer and a tetraethylorthosilicate (TEOS) layer. Formation of the BPSG comprises depositing BPSG material on the passivation layer and polishing until the passivation layer is exposed. As well, the thickness of the BPSG layer can be about 5900˜7300 Å, and of the TEOS layer about 3600˜4400 Å.

The material of the metal layer may comprise tungsten (W).

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1A through 1I are cross-sections illustrating a method of forming a bit line contact hole according to the invention;

FIG. 2A is a flowchart illustrating a conventional method of forming a bit line contact hole;

FIG. 2B is a flowchart illustrating a method of forming a bit line contact hole according to the invention;

FIG. 3 is a cross-section illustrating the conventional bit line contact hole open problem;

FIG. 4 is a cross-section illustrating the conventional bit line contact hole short problem.

### DETAILED DESCRIPTION OF THE INVENTION

A preferred embodiment of the present invention is now described with reference to the figures.

While DRAM is used here as an example, the method of fabricating a bit line contact hole of the present invention is equally well suited for use with other memory devices.

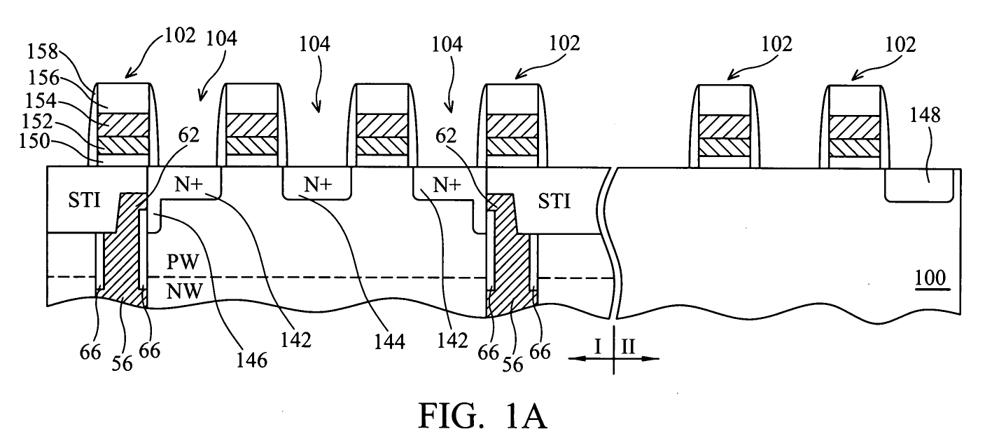

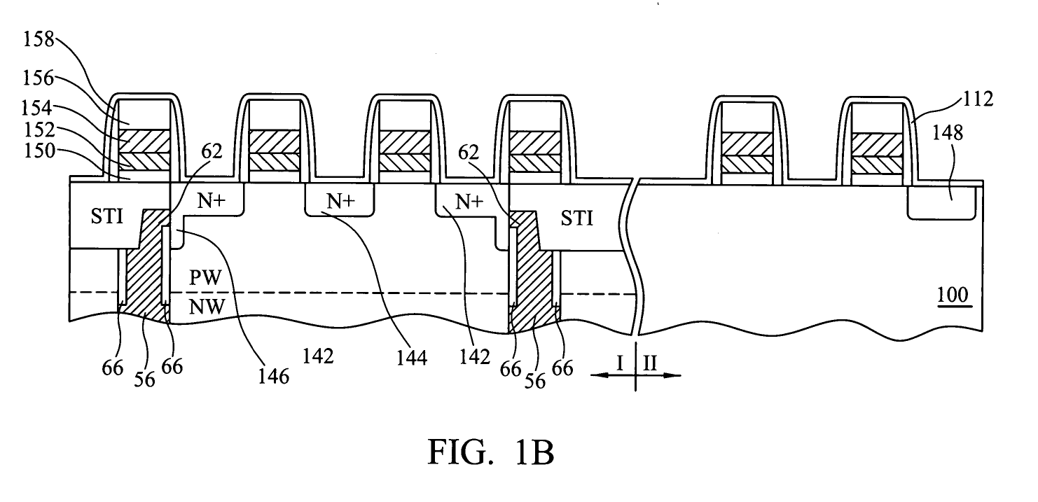

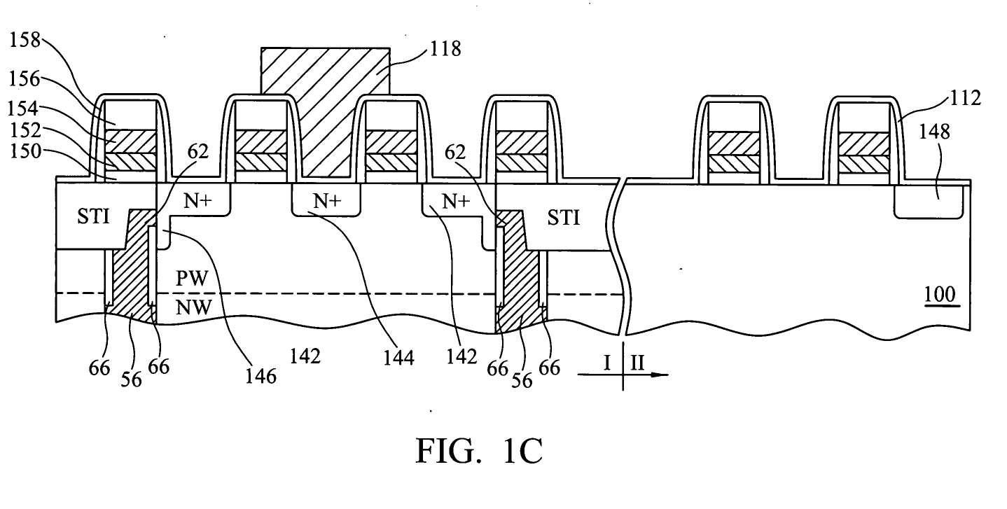

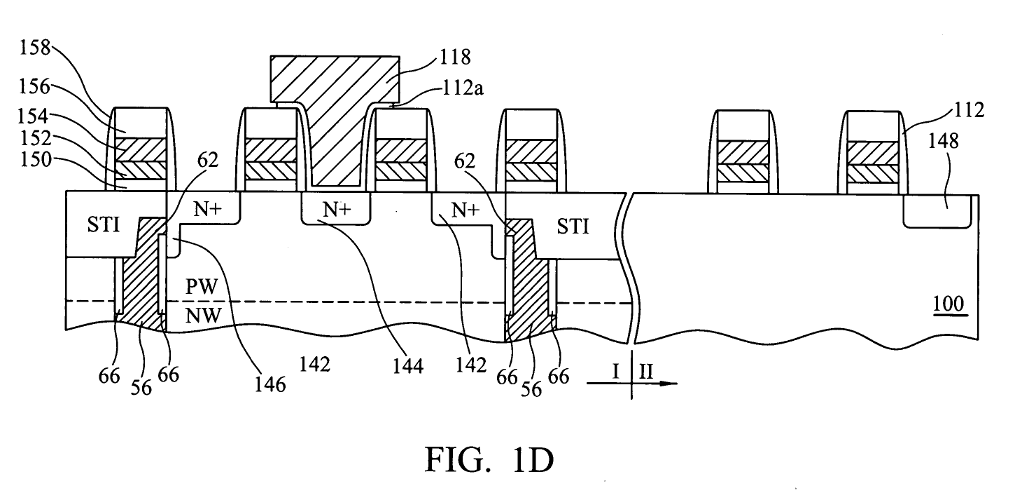

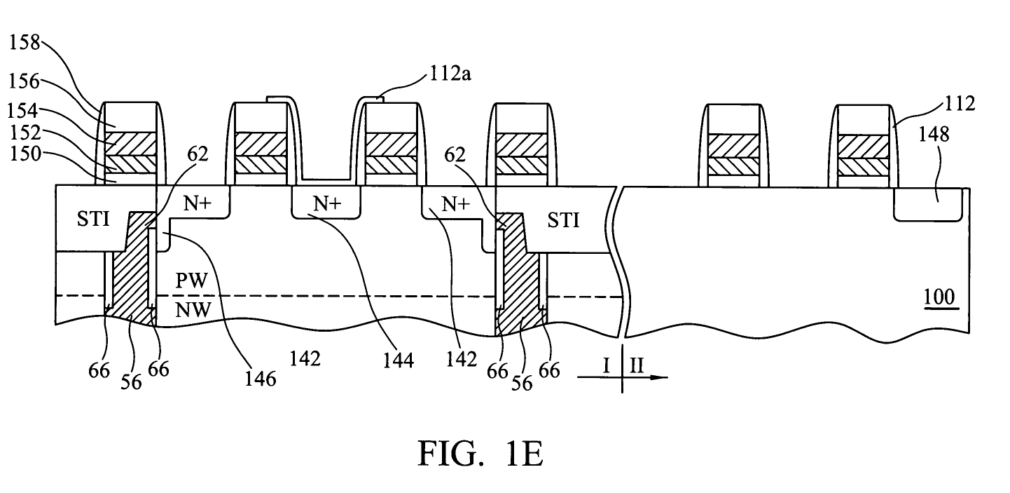

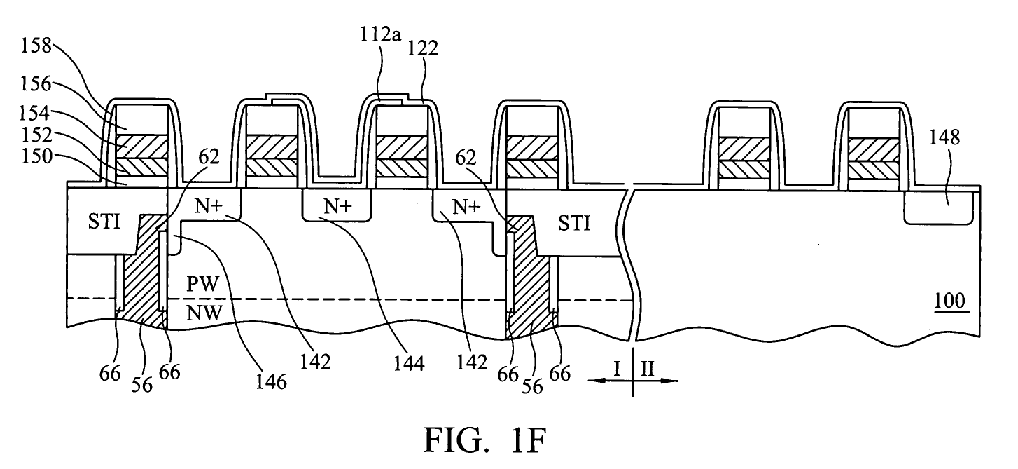

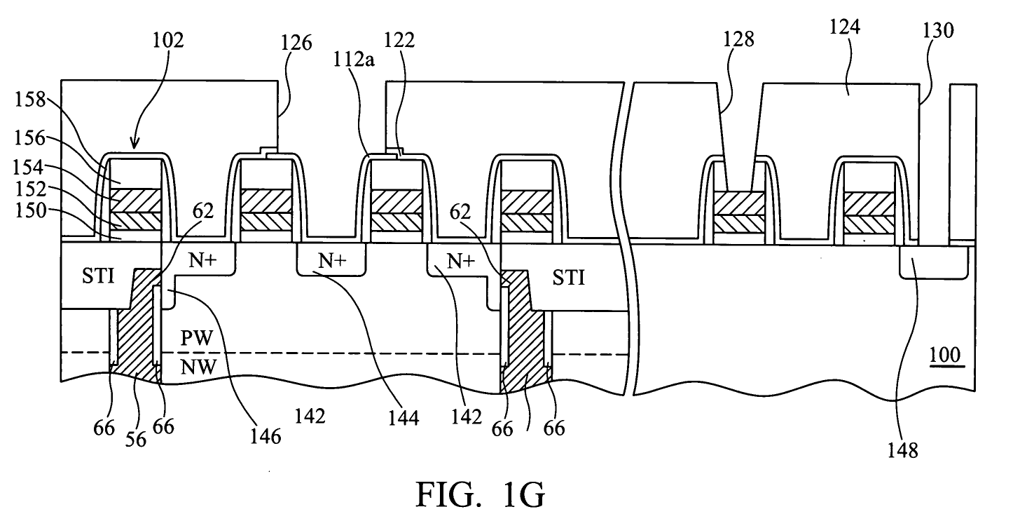

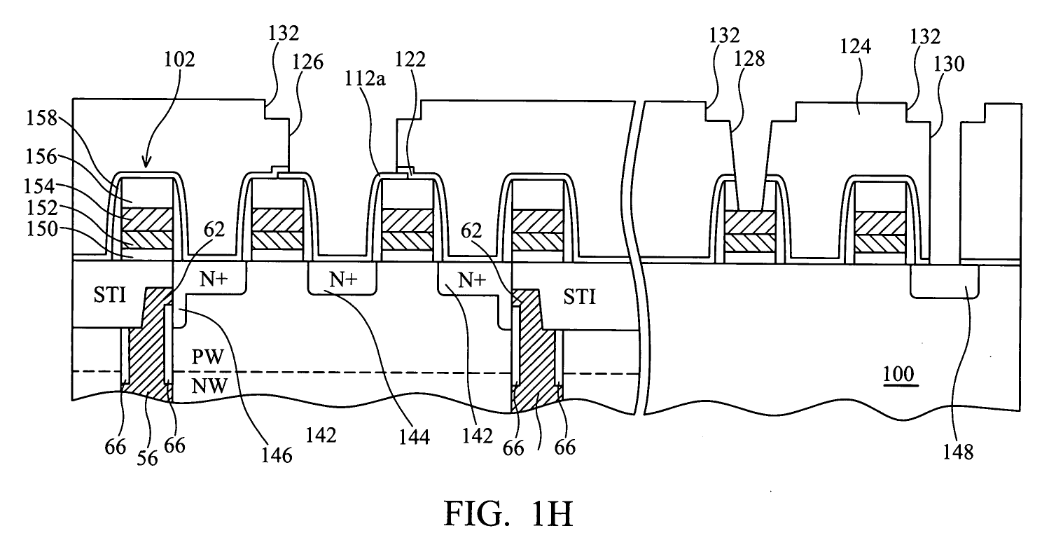

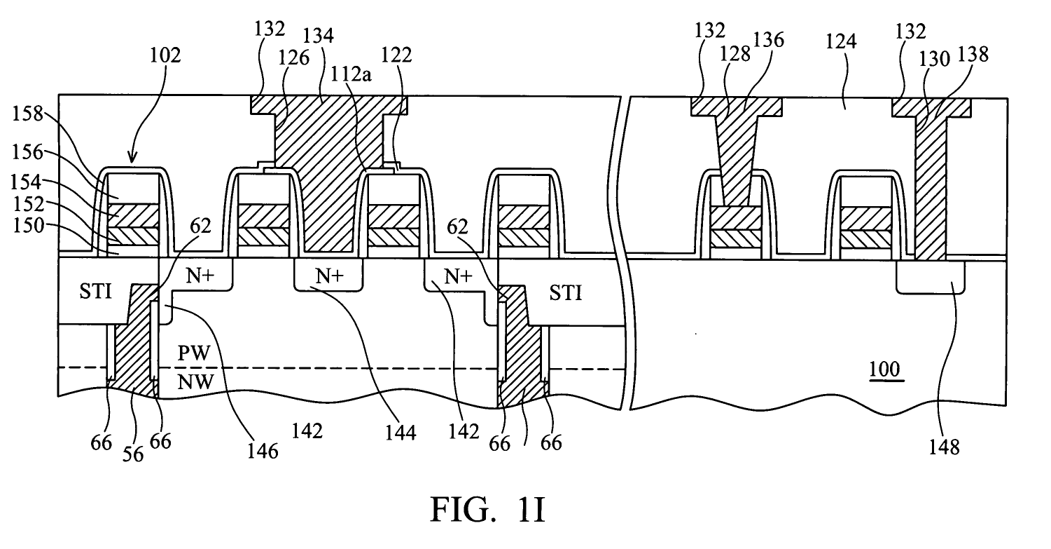

In FIG. 1, a substrate 100, such as a silicon substrate, is provided. The substrate 100 comprises a memory cell array area I and a logic circuit area II. Trench capacitors are formed in the substrate 100. Subsequently, transistors 102 are formed on the substrate 100.

The capacitor is arranged under a passing word line 102. A dielectric collar 66 is formed between a storage node 56 and a doped p type well (PW) as an electrical insulator. A shallow trench insulator (STI) is formed on the storage node 56 to prevent the passing word line 102 and the storage node 56 from electrically connecting. A doped region 142 formed beside the transistor 102 in the substrate 100 electrically connects with a buried strap 62 via a buried strap diffusion 146.

The transistor 102 comprises a source 142, a drain 144, a gate insulating layer 150, a polysilicon layer 152, a metal silicide layer 154, and a cap layer 156. Each of the gate layers is stacked by the polysilicon layer 152 and the metal silicide layer 154. The cap layer 156, comprising silicon nitride, is deposited to cover the top surface of the gate layer, and a spacer 158 comprising silicon nitride is deposited to cover the sidewall of the gate layer, such that the gate layer is entirely insulated. Doped regions are formed in the substrate 100 to serve as the source 142 and the drain 144. In the memory cell array area I, NMOS type transistors 102 are closely arranged, and gaps 104 adjacent the transistors 102 are formed. As well, in the logic circuit area II, both NMOS type and PMOS type transistors 102 are formed therein.

In FIG. 1B, a polysilicon layer 112 is formed to conformally cover the substrate 100 and the transistors 102. The thickness of the polysilicon layer 112 is preferably about 100˜400 Å.

In FIG. 1C, a mask layer 118, such as a photoresist layer, is formed on the polysilicon layer 112. The polysilicon layer 112 is subsequently defined and etched using the mask layer 118 as a shield to form an inner landing pad 112a connecting with the doped region (the drain 144) in the memory cell array area I, as shown in FIG. 1D. When forming the inner landing pad 112a, the polysilicon layer 112 is preferably etched by wet etching employing a buffered oxide etch (BOE) comprising NH₄F and HF of a preferred ratio of about 400˜500:1. The etching rate of the polysilicon is about 10 Å/minute, and of the silicon substrate 100, about 0.25 Å/minute. The selectivity of the etching agent to the polysilicon is higher than that to the silicon. As well, the etching time is short because of the thinner polysilicon. Thereby, the substrate 100 can not be damaged during etching.

The mask layer 118 is then removed to expose the inner landing pad 112a, as shown in FIG. 1E.

In FIG. 1F, a passivation layer 122 comprising an insulating material, such as silicon nitride, is conformally formed on the inner landing pad 112a, the transistors 102, and the substrate 100 with a thickness of about 110˜130 Å.

An insulating layer 124 with a flat surface is then formed on the passivation layer 122, which preferably comprises stacked BPSG layer of about 5900˜7300 Å and TEOS layer of 3600˜4400 Å. When forming the insulating layer 124, the deposited BPSG layer undergoes chemical mechanical polishing (CMP) until passivation layer 122 is exposed, and the TEOS layer is then deposited. The preformed passivation layer 122 prevents BPBG from diffusing into the transistor 102 or the substrate 100.

In FIG. 1G, a contact hole 126 to the gate layer in memory cell array area I, a contact hole 128 to the gate layer in the logic circuit area II, and a contact hole 130 to the drain 148 logic circuit area II are formed in the insulating layer 124 and the passivation layer 122 during the same process. The contact hole 126 exposes the surface of the inner landing pad 112a in the memory cell array area I, the contact hole 128 exposes the gate layer of the transistor 102 in the logic circuit area II, and the contact hole 130 exposes the doped region 148 of the transistor 102 in the logic circuit area II.

The MO formation process is illustrated as follows, as shown in FIGS. 1H and 1I In FIG. 1H, the insulating layer 124 is subsequently etched to form an interconnected landing pad open 132 on the contact holes 126, 128, 130.

In FIG. 1I, a metal material comprising tungsten fills the contact holes 126, 128, 130. CMP removes metal material extending beyond the insulating layer 124. Thus, a bit line contact plug 134 with interconnected landing pad and a gate contact plug 136, 138, with interconnected landing pad, are obtained.

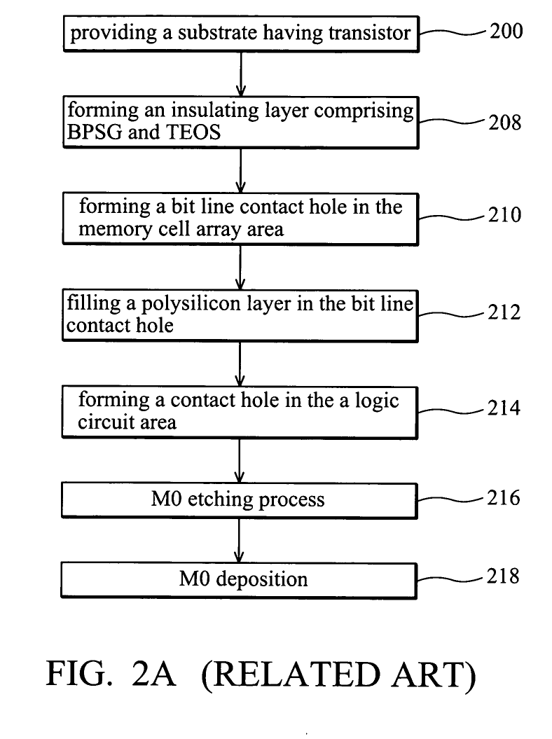

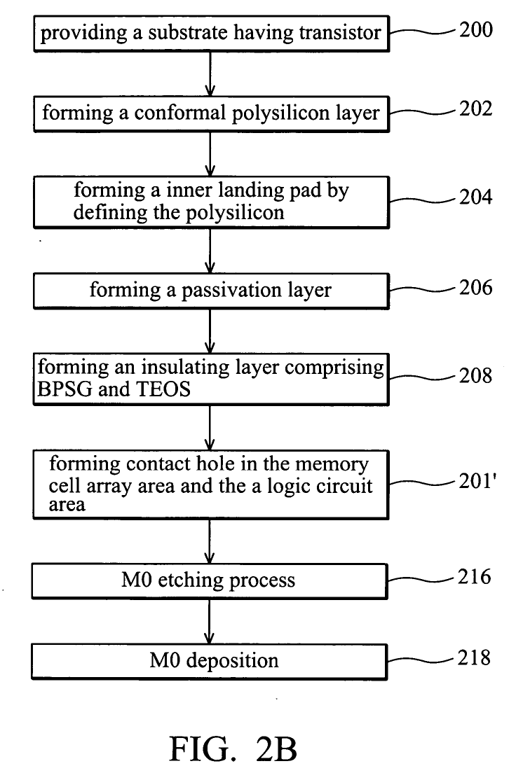

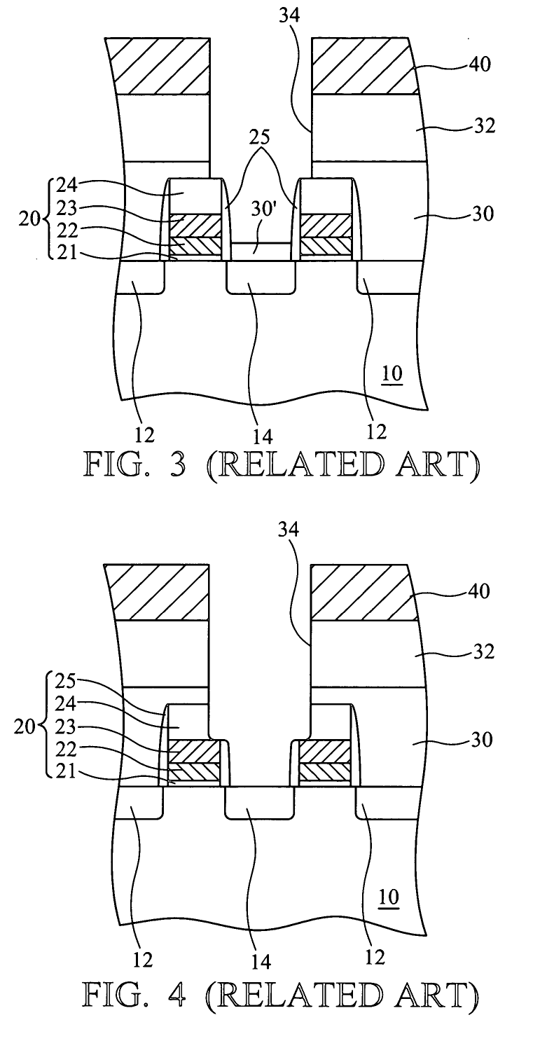

For comparison, flowcharts of the invention (FIG. 2B) and the conventional art (FIG. 2A) are shown.

Steps 202, 204, and 206 are the key features of the present invention, regarding forming the polysilicon layer on the substrate with the transistor, etching the polysilicon layer to form the inner landing pad, and forming the conformal passivation layer.

Moreover, conventionally, the contact holes in the memory cell array area and the logic circuit area are formed in different steps 210, 214. According to the present invention, all contact holes in the memory cell array area and the logic circuit area are formed in the same step 201′.

There are several advantages to the present invention. First, the inner landing pad is utilized to enhance the process window of the connect hole, and the interconnected landing pad is utilized to enhance the process window of the interconnecting line. Second, the polysilicon inner landing pad is formed before the insulating layer on the transistor, such that etching time is shortened to avoid silicon substrate consumption, and solve the difficulty of etching contact hole in a narrow gap between adjacent transistors resulting in shorts between word line and bit line.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. A method of forming a bit line contact hole, comprising:
providing a substrate having a transistor thereon, wherein the transistor comprises a gate layer covered by a first insulating layer, and a doped region;
forming a polysilicon layer to conformally cover the substrate and the transistor;
defining the polysilicon layer to form an inner landing pad connecting with the doped region;
conformally forming a passivation layer on the inner landing pad, the transistor, and the substrate;
forming a second insulating layer with a flat surface on the passivation layer;
forming a contact hole in the second insulating layer and the passivation layer to expose the inner landing pad; and
filling a metal layer in the contact hole.

2. The method as claimed in claim 1, wherein the thickness of the polysilicon layer is about 100˜400 Å.

3. The method as claimed in claim 1, wherein the polysilicon layer is defined by wet etching.

4. The method as claimed in claim 3, wherein an etching agent of etching polysilicon comprises an HF solution.

5. The method as claimed in claim 4, wherein the etching agent comprises NH₄F and HF of about 400˜500:1.

6. The method as claimed in claim 1, the material of the passivation layer comprises silicon nitride.

7. The method as claimed in claim 1, wherein the thickness of the passivation layer is about 110˜130 Å.

8. The method as claimed in claim 1, wherein the second insulating layer is a stacked layer comprising a boro-phospho silicate glass (BPSG) layer and a tetraethylorthosilicate (TEOS) layer.

9. The method as claimed in claim 8, wherein formation of the BPSG comprises depositing a BPSG material on the passivation layer and polishing the BPSG material until the passivation layer is exposed.

10. The method as claimed in claim 8, wherein the thickness of the BPSG layer is about 5900˜7300 Å, and the thickness of the TEOS layer is about 3600˜4400 Å.

11. The method as claimed in claim 1, wherein the material of the metal layer comprises tungsten (W).

12. A method of forming a bit line contact hole, suitable for a substrate having a transistor thereon and comprising a memory cell array area and a logic circuit area, the transistor comprising a gate layer covered by a first insulating layer and a doped region, comprising:
forming a polysilicon layer to conformally cover the substrate and the transistor;
defining the polysilicon layer to form an inner landing pad connecting with the doped region in the memory cell array area;
conformally forming a passivation layer on the inner landing pad, the transistor, and the substrate;
forming a second insulating layer with a flat surface on the passivation layer;
forming a first contact hole, a second contact hole, and a third contact hole in the second insulating layer and the passivation layer, wherein the first contact hole exposes the surface of the inner landing pad in the memory cell array area, the second contact hole exposes the gate layer of the transistor in the logic circuit area, and the third contact hole exposes the doped region of the transistor in the logic circuit area; and
filling a metal layer in the first contact hole, the second contact hole, and the third contact hole.

13. The method as claimed in claim 12, wherein the thickness of the polysilicon layer is about 100˜400 Å.

14. The method as claimed in claim 12, wherein the polysilicon layer is defined by wet etching.

15. The method as claimed in claim 14, wherein an etching agent of etching polysilicon comprises an HF solution.

16. The method as claimed in claim 15, wherein the etching agent comprises NH₄F and HF of about 400˜500:1.

17. The method as claimed in claim 12, the material of the passivation layer comprising silicon nitride.

18. The method as claimed in claim 12, wherein the thickness of the passivation layer is about 110˜130 Å.

19. The method as claimed in claim 12, wherein the second insulating layer is a stacked layer comprising a boro-phospho silicate glass (BPSG) layer and a tetraethylorthosilicate (TEOS) layer.

20. The method as claimed in claim 19, wherein formation of the BPSG comprises depositing a BPSG material on the passivation layer and polishing the BPSG material until the passivation layer is exposed.

21. The method as claimed in claim 19, wherein the thickness of the BPSG layer is about 5900˜7300 Å, and the thickness of the TEOS layer is about 3600˜4400 Å.

22. The method as claimed in claim 12, wherein the material of the metal layer comprises tungsten (W).

23. A structure for a bit line contact hole, comprising:
a substrate;
a transistor, disposed on the substrate, comprising a gate layer covered by a first insulating layer and a doped region;
an inner landing pad, disposed on the doped region and parts of the transistor, comprising a polysilicon layer;
a passivation layer, disposed on the inner landing pad, the transistor, and the substrate;
a second insulating layer, disposed on the passivation layer, having a flat surface on the passivation layer;
a contact plug, disposed on the second insulating layer and the passivation, electrically connecting with the inner landing pad; and
an interconnected landing pad, deposited on the contact plug.

24. The structure as claimed in claim 23, wherein thickness of the polysilicon of the inner landing pad is about 100˜400 Å.

25. The structure as claimed in claim 23, wherein the material of the passivation comprises silicon nitride.

26. The structure as claimed in claim 25, wherein thickness of the passivation is about 110˜130 Å.
